(19) United States
(12) Patent Application Publication
(10) Pub. No.: US 2026/0157226 A1
(43) Pub. Date: Jun. 4, 2026

(54) SOLDER MASK DEFINED UNDERFILL MATERIAL APPLICATION CONTROL

(71) Applicant: BAE Systems Information and Electronic Systems Integration Inc., Nashua, NH (US)

(72) Inventors: Kyle Snyder, Marion, IA (US); Alan P. Boone, Swisher, IA (US); Jacob R. Mauermann, Marion, IA (US)

(73) Assignee: BAE Systems Information and Electronic Systems Integration Inc., Nashua, NH (US)

(21) Appl. No.: 18/968,043

(22) Filed: Dec. 4, 2024

(51) Int. Cl. H01L 23/00; H01L 23/31

(52) U.S. Cl. CPC H10W 74/141; H10W 72/01308; H10W 72/07302; H10W 72/387; H10W 90/734

(57) ABSTRACT

An electronic component includes a substrate having a surface; a solder mask on a portion of the surface of the substrate, the solder mask having at least one control feature defined by a gap between a first portion of the solder mask and a second portion of the solder mask; at least one electronic component having an edge spaced apart from the gap by a distance; and an underfill material located between the edge of the at least one electronic component and the at least one control feature, the gap being devoid of the underfill material.

### FIELD OF DISCLOSURE

The present disclosure relates to material application control, and more particularly, to techniques for using a solder mask to regulate the application of underfill material onto a surface.

### BACKGROUND

Underfill is an encapsulant material used to fill spaces between an electronic component (e.g., a die) and a substrate or carrier upon which the electronic component is mounted. Typically, the encapsulant is an epoxy or polymer that binds the semiconductor to the substrate and protects solder connections between the electronic component and the substrate from wear or damage due to environmental conditions such as vibration, dust, moisture, and variations in temperature. Depending on the type of material and fabrication technique, an underfill material may be deposited onto the substrate before or after the electronic component and/or other connections are attached to the substrate. While various underfill techniques can be used, the quality of the application using such techniques may be limited by factors such as component placement. Therefore, non-trivial issues remain with respect to underfill application techniques.

### BRIEF DESCRIPTION OF THE DRAWINGS

FIG. 1 is a top view of an electronic device having a substrate and at least one electronic component mounted onto the substrate, in accordance with an example of the present disclosure.

FIG. 2 is a top view of an electronic device having a substrate and at least one electronic component mounted onto the substrate, with one or more solder mask control features for underfill material application, in accordance with an example of the present disclosure.

FIG. 3 is a side view of an electronic device of FIG. 2, in accordance with an example of the present disclosure.

FIG. 4 is a side view of an electronic device without any solder mask control features, in accordance with another example of the present disclosure.

FIGS. 5A and 5B are side views of electronic devices with solder mask control features for underfill material application, in accordance with examples of the present disclosure.

FIG. 6 is a side view of an electronic device with solder mask control features of varying depths, in accordance with an example of the present disclosure.

FIG. 7 is a side view of an electronic device with solder mask control features and an electrical interconnect printed on an underfill material, in accordance with an example of the present disclosure.

FIG. 8 is a side view of an electronic device with solder mask control features and an electrical interconnect encapsulated in an underfill material, in accordance with an example of the present disclosure.

FIG. 9 is a flow diagram of an electronic device fabrication method, in accordance with an example of the present disclosure.

Although the following detailed description refers to illustrative examples, many alternatives, modifications, and variations thereof will be apparent in light of this disclosure. The figures are not necessarily drawn to scale.

### DETAILED DESCRIPTION

Techniques for solder mask defined underfill application control are disclosed. In accordance with an example of the present disclosure, an electronic device includes a substrate having a surface and a solder mask on a portion of the surface of the substrate. The solder mask has at least one control feature defined by a gap between a first portion of the solder mask and a second portion of the solder mask. The electronic device further includes at least one electronic component, such as a die, mounted to the substrate and having an edge spaced apart from the gap by a distance. The electronic component can be a single component (e.g., a transistor) or a collection of components on a die or substrate (e.g., active devices such as transistors and diodes and/or passive devices such as resistors, capacitors, and inductors). An underfill material is located at least between the edge of the electronic component(s) and the control feature(s), where the gap is devoid of the underfill material. In some examples, an electrical interconnect is printed on a surface of the underfill material or encapsulated within the underfill material, where the interconnect extends from the electronic component to an electrical contact on the substrate.

Wetting of the underfill material during application is constrained by the control feature(s) with respect to the electronic component(s). The term wetting, in addition to its plain and ordinary meaning, describes the ability of the underfill material, when applied to or deposited on the substrate, to spread out across the substrate. For example, wetting of the underfill material is constrained by the control feature(s) such that during application the underfill material extends to and not into or beyond the control feature(s). In some examples, the gap extends entirely through the solder mask to the substrate, while in other examples, the gap extends partially through the solder mask toward the substrate. The wetting of the underfill material during application can, in some examples, be controlled by a surface energy of the solder mask as well as by the control feature(s). In some examples, a filet of the underfill material extends along an axis perpendicular to the surface of the substrate from the control feature(s) to a portion of the edge(s) of the electronic component(s) distal from the surface of the substrate. Other examples will be apparent in view of the present disclosure.

Electronic Device with Underfilled Components

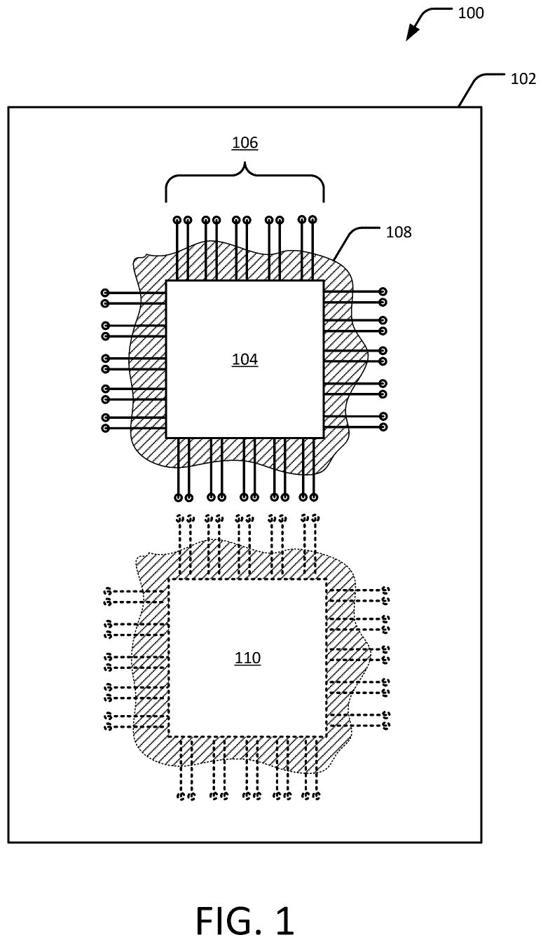

FIG. 1 is a top view of an electronic device 100 having a substrate 102 and at least one electronic component 104 mounted onto the substrate 102, in accordance with an example of the present disclosure. The substrate 102 can include, for example, a printed circuit board with one or more traces 106 printed onto the substrate 102. The electronic component 104 can, for example, be a semiconductor chip, or die, that is electronically coupled to the traces 106. The electronic component 104 may be at least partially underfilled with an underfill material 108.

Advancements in electronics density has driven a reduction in part-to-part spacing. This increase in part density has led to underfill application and control issues, particularly for depositing an underfill material on or near components that have mixed solder joint metallurgy or insufficient interconnect reliability. For instance, some underfill application techniques rely on damming operations or the surface energy and volume of material applied to the substrate for controlling the application of the underfill material, which may not be sufficient for dense packaging. Underfill material binds the electronic component to the substrate and protects solder connections between the electronic component and the substrate from wear or damage due to environmental conditions such as vibration, dust, moisture, and variations in temperature. Thus, the ability to control the application of the underfill material is useful in achieving these ends.

For example, as depicted in FIG. 1, application of the underfill material 108 may be uneven or uncontrolled in all dimensions (horizontal and vertical), which may limit how close the ends of the leads 106 can be located to the edge of the electronic component 104. For instance, due to the difficultly in controlling underfill application (e.g., irregular or otherwise uncontrolled bleed out of the underfill material 108 across the substrate 102), the leads 106 may be longer to avoid being covered by the underfill material 108. This decreases the density of adjacent components on the substrate 102, such as electronic component 110 adjacent to electronic component 104. In some cases, secondary application of damming materials and corresponding cure exposures can be used to improve application control; however, such techniques are costly and time-consuming. Other underfill application techniques, such as wetting and damming, are limited by a non-predictable substrate surface energy or a secondary damming material. These techniques provide inconsistent results and add additional time to assembly processing.

Electronic Device with Solder Mask Defined Underfill Material Application Control

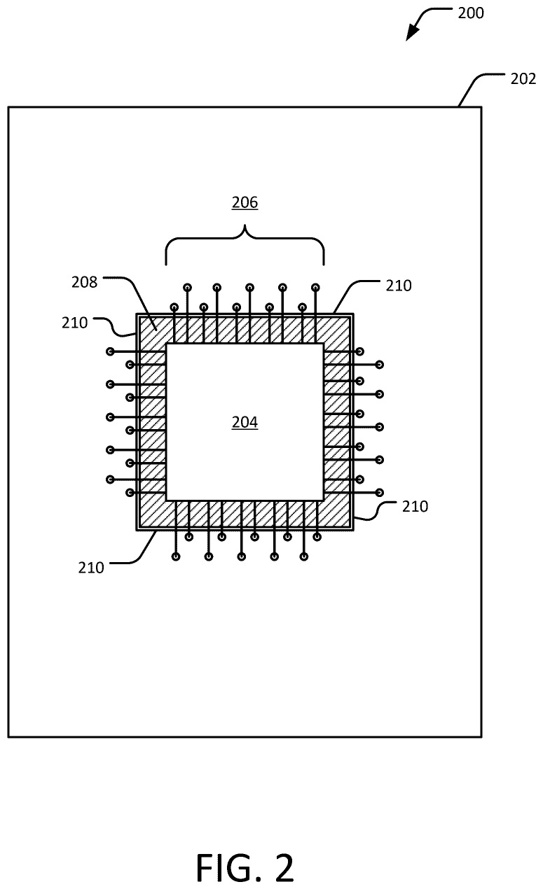

FIG. 2 is a top view of an electronic device 200 having a substrate 202 and at least one electronic component 204 mounted onto the substrate 202, in accordance with an example of the present disclosure. The substrate 202 can include, for example, a printed circuit board with one or more traces 206 printed onto the substrate 202. The electronic component 204 can, for example, be a semiconductor chip, or die, that is electronically coupled to the traces 206. The electronic component 204 can be a single component (e.g., a transistor) or a collection of components on a die or substrate (e.g., active components such as transistors and diodes and/or passive components such as resistors, capacitors, and inductors), or any other individual, collection, or package of components that are part of an electrical circuit. An electrical circuit can include, for example, components providing an analog circuit, a digital circuit, and electronic or nonlinear circuit (with, e.g., nonlinear components), a filter circuit, or any other type of circuitry. The electronic component 204 is underfilled with an underfill material 208. In some examples, the wetting of the underfill material 208 can be controlled by a combined use of a solder mask control feature 210, as described in further detail below, and a selection of the solder mask material based on surface energy in line with desired flow characteristics. In any case, the solder mask control feature 210 controls the application of the underfill material 208 without any secondary processing steps. This allows greater underfill control and simplified material application. In some examples, the solder mask control feature 210 is formed over the entire periphery of the electronic component 204. However, in some other examples, the solder mask control feature 210 is employed on certain areas that require such bounding.

The solder mask and the underfill material each possess properties that influence wetting of the underfill material. For example, the wetting properties of the underfill material are influenced by a combination of surface tension of the underfill material and the surface energy of the solder mask. Surface energy is typically measured in dynes. For example, the surface energy of polytetrafluoroethylene (PTFE) is approximately 18, whereas an epoxy/solder mask has a surface energy of approximately 45. Given a sufficient surface tension of the underfill material 208 and a sufficient surface energy of the solder mask, the wetting of the underfill material 208 can be controlled such that, during application, the underfill material 208 remains on the solder mask material but does not extend into or otherwise overflow the solder mask control feature 210, keeping the solder mask control feature 210 devoid of the underfill material 208.

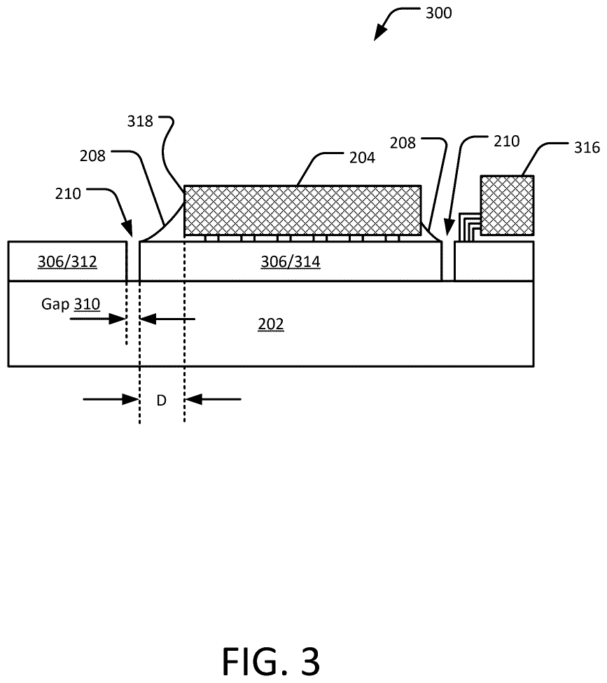

FIG. 3 is a side view of an electronic device 300 having the substrate 202 and the electronic component 204 of FIG. 2 mounted onto the substrate 202, in accordance with an example of the present disclosure. Note that FIG. 3 is not drawn to scale so that features of the electronic device 300 are more readily visible. The electronic device 300 is similar to the electronic device 200 of FIG. 2, although it will be understood that the electronic device 300 may include additional and/or fewer components, such as an underfill-sensitive component 316 that should not be impinged by the underfill material 208. The substrate 202 can include, for example, a printed circuit board such as described with respect to FIG. 2. The electronic component 204 can, for example, be a semiconductor chip, or die.

The electronic component 300 includes a solder mask 306 applied to a portion of a surface of the substrate 202. The electronic component 204 is underfilled with the underfill material 208. The wetting of the underfill material 208 is controlled by the solder mask control feature 210. The solder mask control feature 210 controls the application of the underfill material 208 such that the underfill material 208 flows up to, but no farther than, the solder mask control feature 210. The solder mask control feature 210 is defined by a downward transition of the solder mask 306 to the laminate material of the substrate 202 or other underlying structure, forming a gap 310 between a first portion 312 of the solder mask 306 and a second portion 314 of the solder mask 306. In some examples, the downward transition can be relatively sharp with a zero or near-zero radius. Such a sharp radius at the downward transition of the solder mask 306 at the solder mask control feature 210 improves the ability of the surface tension of the underfill material 208 and/or the surface energy of the solder mask 306 to prevent the underfill material 208 from overflowing into or across the solder mask control feature 210. In this manner, the solder mask control feature 210 facilitates controlling the extent of the wetting of the underfill material 208 to the edge of the solder mask control feature 210, and no further.

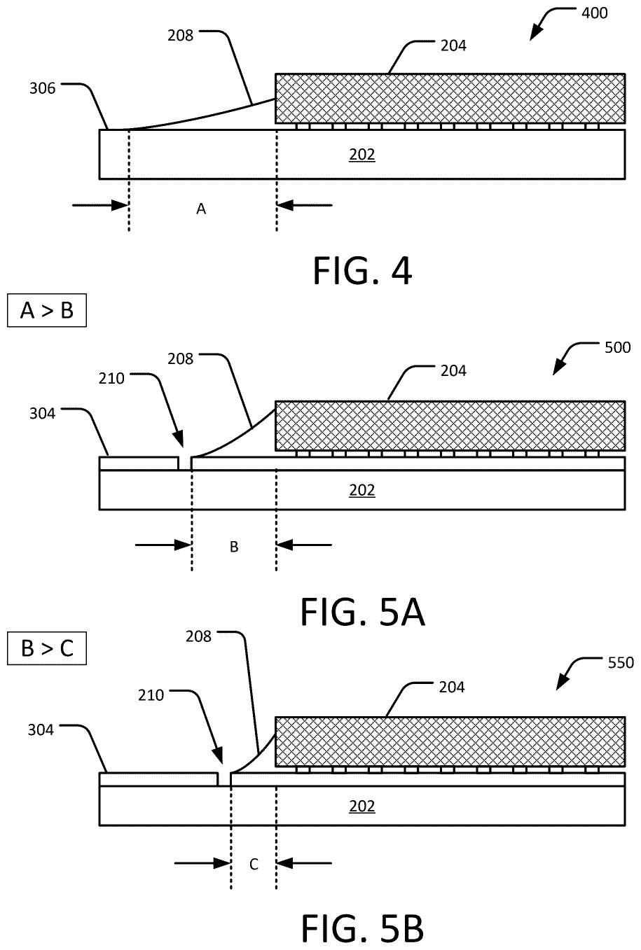

The electronic component 204 has an edge 318 spaced apart from the gap 310 by a distance D. The geometry (slope) of the underfill material 208 between the edge 318 of the electronic component 204 and the solder mask 306 can be controlled by the distance D. For example, the geometry of the underfill material 208 may be steeper for a smaller distance D than for a larger distance D, such as described in further detail with respect to FIGS. 4, 5A and 5B.

FIG. 4 is a side view of an electronic device 400 having the substrate 202 and the electronic component 204 of FIG. 2 mounted onto the substrate 202, in accordance with an example of the present disclosure. The electronic device 400 has no solder mask control feature. Thus, the wetting of the underfill material 208 is unconstrained. This may cause the underfill material 208 to extend a distance A away from the electronic component 204. The distance A may reduce or otherwise limit the density of components on the substrate 202 due to the extent of the underfill material 208 across the surface of the substrate 202.

FIGS. 5A and 5B are side views of an electronic device 500 and 550 each having the substrate 202 and the electronic component 204 of FIG. 2 mounted onto the substrate 202, in accordance with examples of the present disclosure. Wetting of the underfill material 208 is constrained by the control feature 210 such that during application the underfill material 208 extends to, but not into or beyond, a region of the electronic device 500 adjacent to the control feature 210 and the gap 310. In particular, the gap 310 defining the control feature 210 is devoid of the underfill material 208, unlike prior application techniques where the underfill flows into, across, or through barriers or trenches. In this manner, the control feature 210 helps prevent application of the underfill material 208 onto portions of the electronic device 300 where the underfill is not desired or needed, such as to prevent the underfill material 208 applied adjacent to the electronic component 204 from impinging on the underfill-sensitive component 316.

In FIG. 5A, the control feature 210 is located a distance B away from the electronic component 204, where the distance A is greater than the distance B. In this manner, the extent and geometry of the underfill material 208 can be more precisely controlled than in the electronic device 400, which has no control features. For example, a filet of the underfill material 208 extends along an axis perpendicular to the surface of the substrate 202 from the control feature 210 to a portion of the edge of the electronic component 204 distal from the surface of the substrate 202.

In FIG. 5B, the control feature 210 is located a distance C away from the electronic component 204, where the distance B is greater than the distance C. In this manner, the extent and geometry of the underfill material 208 can be more precisely controlled than in the electronic device 400, which has no such control features, or in the electronic device 500, where the control feature 210 is spaced farther away from the electronic component 204 than in the electronic device 550. Other variations of the solder mask control feature will be apparent in view of this disclosure. For example, the distance that material flows from the part or die body can be controlled by the location of the solder mask control feature 210 relative to the electronic component 204 to prevent excessive bleed out or to force ramping geometries to support printed interconnect or other similar features.

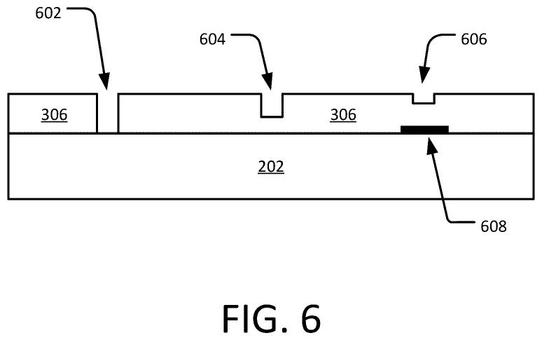

FIG. 6 is a side view of an electronic device 600 having the substrate 202 and the solder mask 306, in accordance with an example of the present disclosure. The electronic device 600 has solder mask control features 602, 604, and 606 formed in the solder mask 306. The depths of the solder mask control features 602, 604, and 606 can vary from partially to completely extending through the solder mask 306 to the surface of the substrate 202. The solder mask control features 602, 604, and 606 are similar to the solder mask control feature 210, as described above, and can be incorporated into the original application of the solder mask 306 or through removal of material from the solder mask 306 subsequent to application, such as by laser, plasma, material deposition, reactive-ion etching, or other additive and/or subtractive techniques, such as three-dimensional printing or mechanical removal. In some examples, the solder mask control features 604 and 606, which do not extend all the way through the solder mask 306, can permit routing of signals beneath the solder mask control features while ensuring coverage of the solder mask 306. For example, an electrical interconnect 608 as shown in FIG. 6 can be routed beneath the solder mask control feature 606.

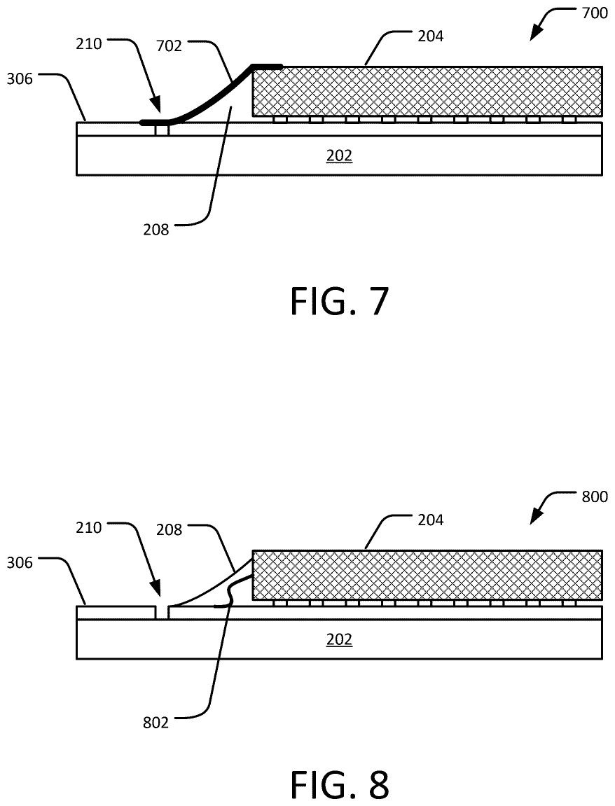

FIG. 7 is a side view of an electronic device 700 having the substrate 202 and the solder mask 306, in accordance with an example of the present disclosure. The electronic device 700 includes the solder mask control feature 210 to control wetting of the underfill material 208, such as described above. The electronic device 700 further includes an electrical interconnect 702 (e.g., printed onto the underfill material 208) that extends from the electronic component 204 to the solder mask 306. When printing the electrical interconnect 702 on die level assemblies, the underfill geometry consistently and predictably controls the interconnect transition from the die surface to the mating board plane.

FIG. 8 is a side view of an electronic device 800 having the substrate 202 and the solder mask 306, in accordance with an example of the present disclosure. The electronic device 800 includes the solder mask control feature 210 to control wetting of the underfill material 208, such as described above. The electronic device 800 further includes an electrical interconnect 802 (e.g., encapsulated within the underfill material 208) that extends from the electronic component 204 to the solder mask 306 and, in some examples, extends to a trace (e.g., traces 206 of FIG. 2). The disclosed techniques allow the horizontal and vertical flow characteristics of the underfill material 208 to be controlled and adapted to fit the desired implementation, such as shown in FIG. 8.

The disclosed examples can be incorporated into designs to allow for a significant increase in part density for adjacent or surrounding parts that may require underfill, and in particular, when co-populating underfilled components in close proximity to components that are functionally sensitive to underfill. In this manner, the application of damming material can be eliminated or significantly reduced, which reduces or eliminates preparation time and the associated removal of the damming material. Furthermore, the disclosed examples can increase yields on products for assemblies that require underfill in dense and hard to dispense locations. The disclosed examples allow high complexity assemblies to be moved to an automated process.

### Electronic Device Fabrication Methodology

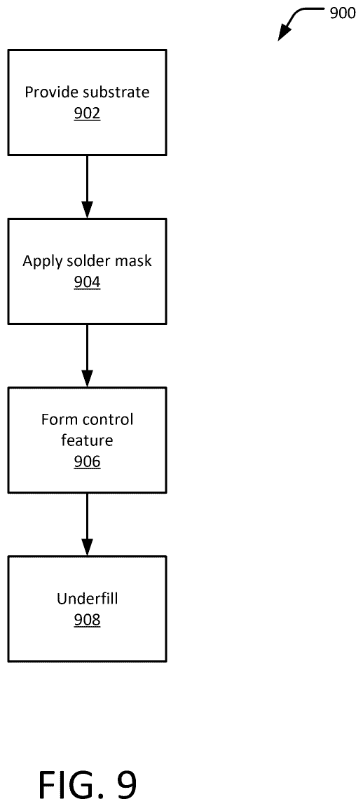

FIG. 9 is a flow diagram of an electronic device fabrication method 900, in accordance with an example of the present disclosure. The method 900 can be used, for example, to fabricate any of the electronic devices 200, 300, 400, 500, 550, 600, 700, and/or 800 of FIGS. 2-8, or variations of these devices. The method 900 includes providing 902 a substrate (e.g., the substrate 202) having a surface and applying 904 a solder mask (e.g., the solder mask 306) on a portion of the surface of the substrate.

The method 900 further includes forming 906 at least one control feature (e.g., the control feature 210, 602, 604, and/or 606) in the solder mask, where the control feature(s) is defined by a gap between a first portion of the solder mask and a second portion of the solder mask. The method 900 further includes underfilling 908 an electronic component mounted to the substrate with an underfill material, where the gap is devoid of the underfill material. In this manner, the control feature(s) of the solder mask constrain the application of the underfill to a region adjacent to the gap.

In some examples, wetting of the underfill material is constrained by the control feature(s) such that during application the underfill material extends to and not into or beyond the control feature(s). In some examples, forming the control feature(s) includes removing a portion of the solder mask. In some examples, the gap extends entirely through the solder mask to the substrate, while in some other examples, the gap extends partially through the solder mask.

In some examples, the method 900 further includes printing traces onto the substrate and coupling a component to the traces, where the underfill material encapsulates at least a portion of the traces and the component. In some examples, the method 900 further includes printing an electronic interconnect onto the underfill material. In some examples, the method 900 further includes encapsulating an electronic interconnect within the underfill material.

The terms “circuit” or “circuitry” can include, for example, hardwired circuitry, programmable circuitry, such as computer processors comprising one or more individual instruction processing cores, state machine circuitry, and/or firmware that stores instructions executed by programmable circuitry. The circuit or circuitry can be implemented as part of a larger system, for example, an integrated circuit (IC), an application-specific integrated circuit (ASIC), a system-on-a-chip (SoC), and so forth.

### FURTHER EXAMPLES

The following examples pertain to further examples, from which numerous permutations and configurations will be apparent.

Example 1 provides an electronic device comprising a substrate having a surface; a solder mask on a portion of the surface of the substrate, the solder mask having at least one control feature defined by a gap between a first portion of the solder mask and a second portion of the solder mask; at least one electronic component having an edge spaced apart from the gap by a distance; and an underfill material located between the edge of the at least one electronic component and the at least one control feature, the gap being devoid of the underfill material.

Example 2 includes the subject matter of Example 1, wherein wetting of the underfill material is constrained by the at least one control feature such that during application the underfill material extends to and not into or beyond the at least one control feature.

Example 3 includes the subject matter of Examples 1 or 2, wherein the gap extends entirely through the solder mask to the substrate.

Example 4 includes the subject matter of any one of Examples 1-3, wherein the gap extends partially through the solder mask toward the substrate. In some such examples, electrical interconnects are routed under the gap.

Example 5 includes the subject matter of any one of Examples 1-4, wherein a filet of the underfill material extends along an axis perpendicular to the surface of the substrate from the at least one control feature to a portion of the edge of the at least one electronic component distal from the surface of the substrate.

Example 6 includes the subject matter of any one of Examples 1-5, wherein a wetting of the underfill material during application is constrained by the at least one control feature with respect to the at least one electronic component.

Example 7 includes the subject matter of any one of Examples 1-6, wherein a wetting of the underfill material during application is controlled by a surface energy of the solder mask and/or a surface tension of the underfill material.

Example 8 includes the subject matter of any one of Examples 1-7, wherein the at least one electronic component includes a die.

Example 9 includes the subject matter of Example 8, further comprising an electrical interconnect printed on a surface of the underfill material or encapsulated within the underfill material, the electrical interconnect extending from the at least one electronic component to an electrical contact on the substrate.

Example 10 provides an electronic device comprising a substrate having a surface; and a solder mask on a portion of the surface of the substrate, the solder mask having at least one control feature defined by a gap between a first portion of the solder mask and a second portion of the solder mask.

Example 11 includes the subject matter of Example 10, further comprising an underfill material located adjacent to the gap, the gap being devoid of the underfill material.

Example 12 includes the subject matter of Example 11, wherein wetting of the underfill material is constrained by the at least one control feature such that during application the underfill material extends to and not into or beyond the at least one control feature.

Example 13 includes the subject matter of Examples 11 or 12, wherein a filet of the underfill material extends along an axis perpendicular to the surface of the substrate from the at least one control feature to a portion of the edge of the at least one electronic component distal from the surface of the substrate.

Example 14 provides an electronic device fabrication method comprising providing a substrate having a surface; applying a solder mask on a portion of the surface of the substrate; forming at least one control feature in the solder mask, the at least one control feature defined by a gap between a first portion of the solder mask and a second portion of the solder mask; and underfilling an electronic component mounted to the substrate with an underfill material, the gap being devoid of the underfill material.

Example 15 includes the subject matter of Example 14, wherein wetting of the underfill material is constrained by the at least one control feature such that during application the underfill material extends to and not into or beyond the at least one control feature.

Example 16 includes the subject matter of Examples 14 or 15, wherein the gap extends entirely through the solder mask to the substrate.

Example 17 includes the subject matter of any one of Examples 14-16, wherein forming the at least one control feature includes removing a portion of the solder mask.

Example 18 includes the subject matter of any one of Examples 14-17, further comprising printing traces onto the substrate and coupling the electronic component to the traces, wherein the underfill material encapsulates at least a portion of the traces and the electronic component.

Example 19 includes the subject matter of any one of Examples 14-18, further comprising printing an electronic interconnect onto the underfill material.

Example 20 includes the subject matter of any one of Examples 14-19, further comprising encapsulating an electronic interconnect within the underfill material.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

What is claimed is:

1. An electronic device comprising:
a substrate having a surface;
a solder mask on a portion of the surface of the substrate, the solder mask having at least one control feature defined by a gap between a first portion of the solder mask and a second portion of the solder mask;
at least one electronic component having an edge spaced apart from the gap by a distance; and
an underfill material located between the edge of the at least one electronic component and the at least one control feature, the gap being devoid of the underfill material.

2. The electronic device of claim 1, wherein wetting of the underfill material is constrained by the at least one control feature such that during application the underfill material extends to and not into or beyond the at least one control feature.

3. The electronic device of claim 1, wherein the gap extends entirely through the solder mask to the substrate.

4. The electronic device of claim 1, wherein the gap extends partially through the solder mask toward the substrate.

5. The electronic device of claim 4, wherein electrical interconnects are routed under the gap.

6. The electronic device of claim 1, wherein a filet of the underfill material extends along an axis perpendicular to the surface of the substrate from the at least one control feature to a portion of the edge of the at least one electronic component distal from the surface of the substrate.

7. The electronic device of claim 1, wherein a wetting of the underfill material during application is constrained by the at least one control feature with respect to the at least one electronic component.

8. The electronic device of claim 1, wherein a wetting of the underfill material during application is controlled by a surface energy of the solder mask and/or a surface tension of the underfill material.

9. The electronic device of claim 1, wherein the at least one electronic component includes a die.

10. The electronic device of claim 9, further comprising an electrical interconnect printed on a surface of the underfill material or encapsulated within the underfill material, the electrical interconnect extending from the at least one electronic component to an electrical contact on the substrate.

11. An electronic device comprising:
a substrate having a surface; and
a solder mask on a portion of the surface of the substrate, the solder mask having at least one control feature defined by a gap between a first portion of the solder mask and a second portion of the solder mask.

12. The electronic device of claim 11, further comprising an underfill material located adjacent to the gap, the gap being devoid of the underfill material.

13. The electronic device of claim 12, wherein wetting of the underfill material is constrained by the at least one control feature such that during application the underfill material extends to and not into or beyond the at least one control feature.

14. The electronic device of claim 12, wherein a filet of the underfill material extends along an axis perpendicular to the surface of the substrate from the at least one control feature to a portion of the at least one electronic component distal from the surface of the substrate.

15. An electronic device fabrication method comprising:
providing a substrate having a surface;
applying a solder mask on a portion of the surface of the substrate;
forming at least one control feature in the solder mask, the at least one control feature defined by a gap between a first portion of the solder mask and a second portion of the solder mask; and
underfilling an electronic component mounted to the substrate with an underfill material, the gap being devoid of the underfill material.

16. The method of claim 15, wherein wetting of the underfill material is constrained by the at least one control feature such that during application the underfill material extends to and not into or beyond the at least one control feature.

17. The method of claim 15, wherein forming the at least one control feature includes removing a portion of the solder mask.

18. The method of claim 15, further comprising printing traces onto the substrate and coupling the electronic component to the traces, wherein the underfill material encapsulates at least a portion of the traces and the electronic component.

19. The method of claim 15, further comprising printing an electronic interconnect onto the underfill material.

20. The method of claim 15, further comprising encapsulating an electronic interconnect within the underfill material.
